(19) United States
(12) Patent Application Publication
(10) Pub. No.: US 2021/0135431 A1
(43) Pub. Date: May 6, 2021

(54) QUANTUM CASCADE LASER

(71) Applicant: SUMITOMO ELECTRIC INDUSTRIES, LTD., Osaka (JP)

(72) Inventors: Jun-ichi HASHIMOTO, Osaka-shi (JP); Hiroyuki YOSHINAGA, Osaka-shi (JP)

(73) Assignee: SUMITOMO ELECTRIC INDUSTRIES, LTD., Osaka (JP)

(21) Appl. No.: 17/086,606

(22) Filed: Nov. 2, 2020

(30) Foreign Application Priority Data
Nov. 5, 2019 (JP) 2019-200631

(51) Int. Cl. H01S 5/34; H01S 5/10

(52) U.S. Cl. CPC H01S 5/3401; H01S 5/028; H01S 5/1096

(57) ABSTRACT

A quantum cascade laser includes a laser structure having an output face for emitting laser light in a first direction, and a reflecting film provided on the output face. The laser structure includes a core layer. The output face includes an end face of the core layer. The end face includes a first region and a second region that differs from the first region. The reflecting film covers the first region and does not cover the second region.

### CROSS REFERENCE TO RELATED APPLICATIONS

The present application is based upon and claims the benefit of the priority from Japanese patent application No. 2019-200631, filed on Nov. 5, 2019, which is hereby incorporated by reference in its entirety.

### TECHNICAL FIELD

The present disclosure relates to a quantum cascade laser.

### BACKGROUND

Qi Jie Wang et al., “High performance quantum cascade lasers based on three-phononresonance design”, APPLIED PHYSICS LETTERS, vol.94, 011103 (2009) discloses a quantum cascade laser.

### SUMMARY

The present disclosure provides a quantum cascade laser including a laser structure having an output face for emitting laser light in a first direction, and a reflecting film provided on the output face. The laser structure includes a core layer. The output face includes an end face of the core layer. The end face includes a first region and a second region that differs from the first region. The reflecting film covers the first region and does not cover the second region.

### BRIEF DESCRIPTION OF THE DRAWINGS

The foregoing and other purposes, aspects and advantages will be better understood from the following detailed description of a preferred embodiment of the invention with reference to the accompanying drawings.

FIG. 1 is a perspective view schematically showing a quantum cascade laser according to an embodiment;

FIG. 2 is a cross-sectional view taken along line II-II shown in FIG. 1.

FIG. 3 is a cross-sectional view taken along line shown in FIG. 1.

FIG. 4 is a front view schematically showing an output face of a quantum cascade laser according to an embodiment.

FIG. 5 is a graph showing an example of relationships between an alumina film thickness and an effective reflectivity in an output face.

FIG. 6 is a graph showing an example of relationships between a width of a slit and an effective reflectivity in an output face;

FIG. 7 is a graph showing an example of relationships between a width of a slit and a threshold current.

FIG. 8 is a graph showing an example of relationships between current and optical output power when a width of a slit is changed.

FIG. 9 is a graph showing examples of the relationships between current and an optical output power when a width of a slit and a thickness of an alumina film is changed.

FIG. 10 is a diagram illustrating a step in a manufacturing process of a quantum cascade laser according to an embodiment;

FIG. 11A is a top view showing a step in a manufacturing process of a quantum cascade laser according to an embodiment.

FIG. 11B is a cross-sectional view taken along line XIb-XIb line shown in FIG. 11A.

FIG. 12 is a top view showing a step in a manufacturing process of a quantum cascade laser according to an embodiment.

### DETAILED DESCRIPTION

### Problem to be Solved by the Present Disclosure

A reflecting film may be provided on an output face of a laser light emitted from a quantum cascade laser. The reflectivity of the reflecting film suitable for obtaining large optical output power and a small threshold current (current required for laser oscillation) is about 50% to 80%. In order to obtain such reflectivity, the thickness of the reflecting film needs to be small, for example, less than 10 nm. However, when forming a metal film to be used as the reflecting film by vapor deposition or sputtering, the metal film is so thin that regions in which metal particles are not deposited may be formed. In addition, since the deposition time of the metal particles is as short as several seconds, the reproducibility of the film formation is low. As described above, it is difficult to control the reflectivity of the laser light in the output face by the thickness of the reflecting film.

The present disclosures provide a quantum cascade laser that can control the reflectivity of the laser light in the output face.

### [Description of Embodiments of the Present Disclosure]

A quantum cascade laser according to an embodiment includes a laser structure having an output face for emitting laser light in a first direction, and a reflecting film provided on the output face. The laser structure includes a core layer. The output face includes an end face of the core layer. The end face includes a first region and a second region that differs from the first region. The reflecting film covers the first region and does not cover the second region.

According to the above quantum cascade laser, a large portion of the laser light is reflected by the reflecting film in the first region of the end face of the core layer. On the other hand, in the second region of the end face of the core layer, a large portion of the laser light is emitted from the output face. Therefore, by adjusting the area ratio of the first region to the second region, the effective reflectivity of the laser light in the output face can be controlled.

The laser structure may include a mesa waveguide including the core layer. The mesa waveguide may extend in the first direction and may project in a second direction intersecting the first direction. The reflecting film may have a slit provided on the second region. The slit may extend in the second direction. By adjusting the width of the slit, the area ratio of the first region and the second region can be adjusted.

The slit may have a width narrower than a width of the mesa waveguide. In this case, the effective reflectivity of the laser light in the output face can be increased.

The slit may have a length greater than a diameter of a spot size of the laser light in the output face in the second direction. In this case, the slit is located over the entire length of the spot size of the laser light in the second direction.

Hereinafter, embodiments of the present disclosure will be described in detail with reference to the accompanying drawings. In the description of the drawings, the same reference numerals are used for the same or equivalent elements, and a repetitive description is omitted.

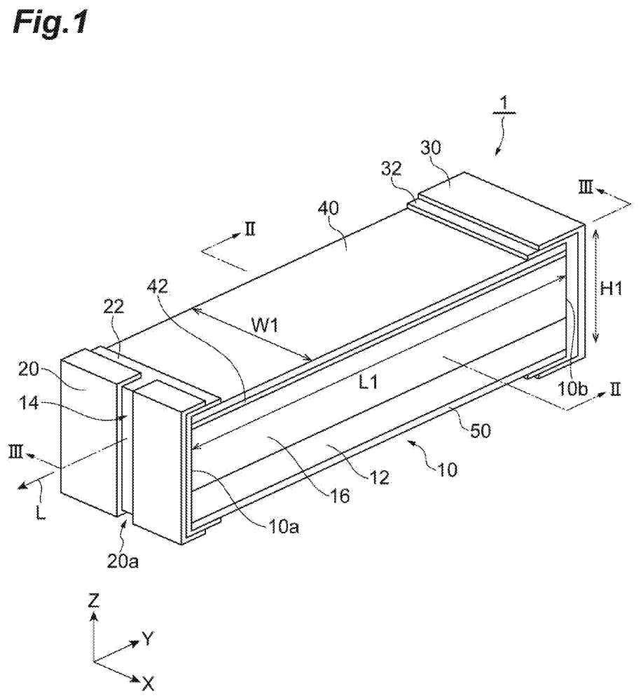

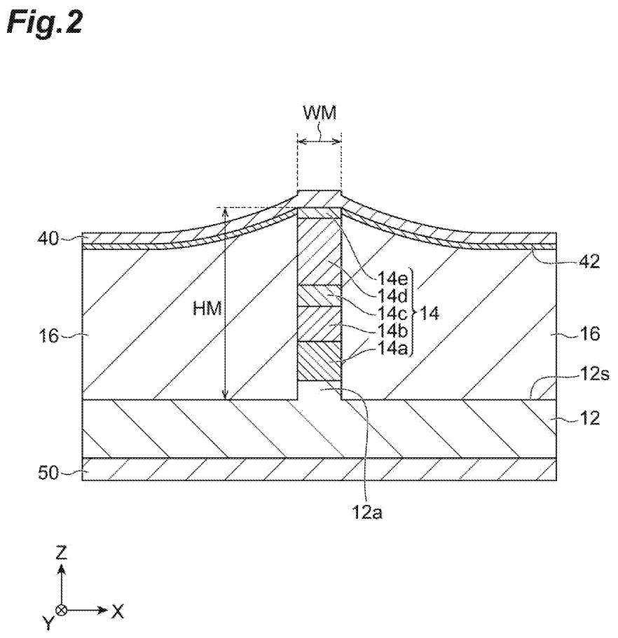

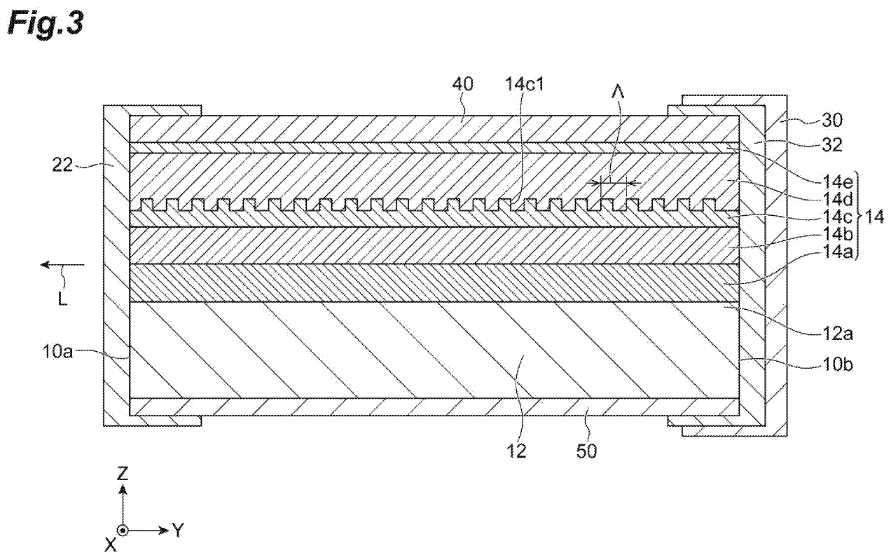

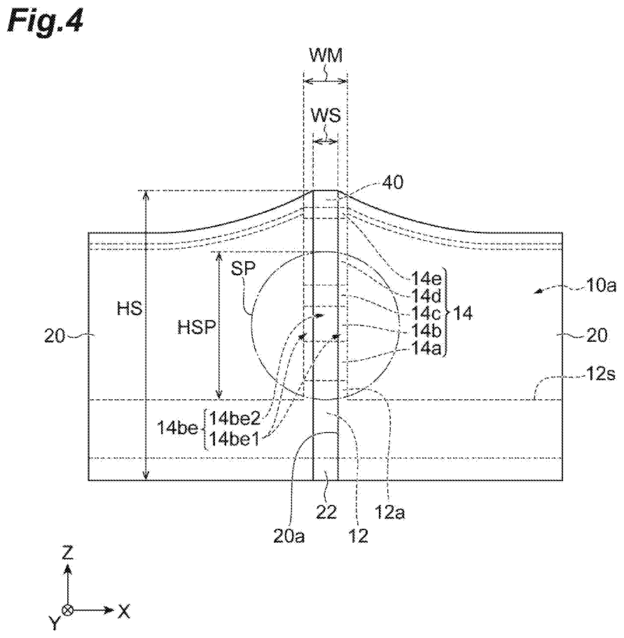

FIG. 1 is a perspective view schematically showing a quantum cascade laser according to an embodiment. FIG. 2 is a cross-sectional view taken along line II-II of FIG. 1. FIG. 3 is a cross-sectional view taken along line of FIG. 1. FIG. 4 is a front view schematically showing an output face of the quantum cascade laser according to an embodiment. FIG. 1 to FIG. 4 show an X-axis direction, a Y-axis direction (first direction) and a Z-axis direction (second direction) intersecting each other. The X-axis direction, the Y-axis direction and the Z-axis direction are, for example, orthogonal to each other.

The quantum cascade laser 1 shown in FIG. 1 to FIG. 4 is used, for example, in industrial laser-processing equipment or optical measurement equipment used in environmental analysis, industrial gas analysis, medical diagnostics, etc. The quantum cascade laser 1 includes a laser structure 10. The laser structure 10 is a resonator capable of oscillating laser light L in the Y-axis direction. The laser structure 10 has an output face 10a for emitting the laser light L in the Y-axis direction and a reflection face 10b opposed to the output face 10a in the Y-axis direction. The output face 10a is a front end face. The reflection face 10b is a rear end face. Each of the output face 10a and the reflection face 10b may be perpendicular to the Y-axis. Each of the output face 10a and the reflection face 10b has, for example, a rectangular configuration. The shape of the laser structure 10 is, for example, a rectangular parallelepiped shape. The laser structure 10 has a length L1 of, for example, 1 to 3 mm in the Y-axis direction, a width W1 of, for example, 400 to 800 μm in the X-axis direction, and a thickness H1 of, for example, 100 to 200 μm in the Z-axis direction.

The laser structure 10 includes a substrate 12, a mesa waveguide 14 provided on principal surfaces 12s of the substrate 12, and current blocking regions 16 for embedding the sides of the mesa waveguide 14. In the X-axis direction, the mesa waveguide 14 is disposed between a pair of the current blocking regions 16. In this case, the laser structure 10 has an buried heterostructure (BH) structure. The current blocking regions 16 are undoped or semi-insulating III-V group compound semiconductor regions such as Fe-doped InP regions.

The substrate 12 is an n-type III-V group compound semiconductor substrate such as n-type InP substrate. The substrate 12 has a protruding part 12a extending along the Y-axis. The mesa waveguide 14 is provided on the protruding part 12a.

The mesa waveguide 14 extends in the Y-axis direction and protrudes in the Z-axis direction. The Y-axis direction is the waveguide direction of the mesa waveguide 14. The mesa waveguide 14 has a height HM from the principal surfaces 12s. The mesa waveguide 14 is a laminate including a plurality of semiconductor layers laminated in the Z-axis direction. The mesa waveguide 14 includes a lower cladding layer 14a provided on the protruding part 12a of the substrate 12, a core layer 14b provided on the lower cladding layer 14a, a grating layer 14c provided on the core layer 14b, an upper cladding layer 14d provided on the grating layer 14c, and a contact layer 14e provided on the upper cladding layer 14d. In the Z-axis direction, the protruding part 12a, the lower cladding layer 14a, the core layer 14b, the grating layer 14c, the upper cladding layer 14d and the contact layer 14e are arranged in this order.

An upper electrode 40 is provided on the contact layer 14e and the current blocking regions 16. A passivation film 42 is provided between the upper electrode 40 and the current blocking regions 16. A lower electrode 50 is provided on the back surface of the substrate 12, the surface facing away from the principal surface 12s. When the quantum cascade laser 1 operates, one of the upper electrode 40 and the lower electrode 50 serves as a cathode electrode and the other serves as an anode electrode. Current is injected into the core layer 14b by applying a predetermined voltage between the upper electrode 40 and the lower electrode 50. As a result, the laser light L is oscillated. The upper electrode 40 and the lower electrode 50 are, for example, Ti/Au films, Ti/Pt/Au films, or Ge/Au films.

The lower cladding layer 14a and the upper cladding layer 14d are n-type group III-V group compound semiconductor layers such as n-type InP layers. InP is transparent to mid-infrared radiation.

The core layer 14b has a structure in which a plurality of active layers and a plurality of injection layers are alternately laminated. Each of the active layers and the injection layers has an array of superlattices in which a plurality of well layers and a plurality of barrier layers are alternately laminated. Each of the well layer and the barrier layer has a thickness of several nm. For example, a GaInAs/AlInAs can be used as an array of the superlattices. Only electrons are used as carriers. Transitions between subbands in the conduction-band oscillate the laser light L in the mid-infrared region (e.g., 7 μm in wavelength).

The grating layer 14c has a plurality of recesses 14c1 periodically arranged at pitches Λ along the Y-axis. The pitch Λ defines the oscillating wavelength λ of the laser light L. Each of the recesses 14c1 is a groove extending in the X-axis direction. As a result, the quantum cascade laser 1 functions as a distributed feedback (DFB) laser. The recesses 14c1 of the grating layer 14c are embedded by the upper cladding layer 14d. The grating layer 14c is a group III-V group compound semiconductor layer such as an undoped or an n-type GaInAs layer.

The contact layer 14e is an n-type III-V group compound semiconductor layer such as an n-type GaInAs layer.

An optical confinement layer may be provided between the lower cladding layer 14a and the core layer 14b. An optical confinement layer may be provided between the grating layer 14c and the core layer 14b. The optical confinement layer is an n-type III-V group compound semiconductor layer such as an undoped or an n-type GaInAs layer.

As the n-type dopant, Si, S, Sn, Se or the like can be used.

The quantum cascade laser 1 includes a reflecting film 20 and a reflecting film 30. The reflecting film 20 is provided on the output face 10a via a passivation film 22. The passivation film 22 covers, for example, the entire surface of the output face 10a. The reflecting film 30 is provided on the reflection face 10b via a passivation film 32. The passivation film 32 and the reflecting film 30 cover, for example, the entire surface of the reflection face 10b. The passivation film 22 and the passivation film 32 are dielectric films or insulating films such as alumina films, SiO₂ films, SiON films and SiN films.

The reflecting film 20 and the reflecting film 30 include, for example, gold. Each of the reflecting films 20 and the reflecting film 30 is, for example, Ti/Au film, Ti/Pt/Au film, or Ge/Au film. The thickness of the reflecting film 20 and the reflecting film 30 may be 10 nm or more, or may be 50 nm or more, or may be 100 nm or more. The thickness of the reflecting film 30 may be 200 nm or less. When the film thickness is 50 nm or more, the reproducibility of the manufacture of reflecting films is improved. Although the reflectivity can be increased by increasing the film thickness, the increase in the reflectivity becomes smaller when the reflecting film becomes thicker than 200 nm. The reflectivity of the reflecting film 20 and the reflecting film 30 with respect to light having a wavelength of 7 μm may be 80% or more, or may be 90% or more. The higher the reflectivity, the lower a threshold current can be.

As shown in FIG. 4, the output face 10a includes an end face of the substrate 12, an end face of the mesa waveguide 14 and end faces of the current blocking regions 16. More specifically, the output face 10a includes an end face 14be of the core layer 14b. The end face 14be includes first regions 14be1 and a second region 14be2 that differs from the first regions 14be1. The reflecting film 20 covers the first regions 14be1 and not the second region 14be2. That is, the reflecting film 20 partially covers the end face 14be of the core layer 14b. In the present embodiment, the second region 14be2 is disposed between the pair of the first regions 14be1 in the X-axis direction.

The reflecting film 20 has a slit 20a provided on the second region 14be2. The slit 20a extends along the Z-axis. A width WS of the slit 20a is smaller than a width WM of the mesa waveguide 14. The reflecting film 20 then covers a portion of the end face of the substrate 12, a portion of the end face of the mesa waveguide 14, and end faces of the current blocking regions 16. In the present embodiment, the passivation film 22 is provided on the output face 10a in the slit 20a. As a result, it is possible to suppress degradation of semiconductor crystals of the output face 10a due to, for example, oxidization. The passivation film 22 may also have a slit corresponding to the slit 20a. In this instance, in the slit 20a, a part of the end face of the substrate 12 and a part of the end face of the mesa waveguide 14 are exposed to the space. This allows the improvement of the heat dissipation in the output face 10a, thereby improving the thermal properties of the quantum cascade laser 1. The width WS of the slit 20a is, for example, 1 μm to 5 μm. The width WM of the mesa waveguide 14 is, for example, 2 to 5 μm. In the Z-axis direction, a length HS of the slit 20a is greater than a diameter HSP of a spot size SP of the laser light L in the output face 10a.

In a region of the output face 10a that is covered with the reflecting film 20, such as the first regions 14be1, the reflectivity with respect to the light having a wavelength of 7 μm is, for example, 90% or more. On the other hand, in a region of the output face 10a that is not covered with the reflecting film 20, such as the second region 14be2, the reflectivity with respect to the light having a wavelength of 7 μm is, for example, 30% or less. The effective reflectivity of the output face 10a with respect to the light having a wavelength of 7 μm is, for example, 20 to 80%. The slit 20a with the width WS of 1 to 5 μm provides effective reflectivity in these ranges.

The effective reflectivity R_{eff} (%) of the output face 10a with respect to the oscillation wavelength is expressed by the following equation (1).

R_{eff}=100−Γ×(1−R/100) (1)

Γ represents the percentage (%) of the light intensity distributed in a region of the output face 10a that is not covered by the reflecting film 20 (the region of the slit 20a). F is calculated by a beam-propagation method (BPM). R represents the reflectivity (%) of the output face 10a with respect to the oscillating wavelength in the absence of the reflecting film 20. For example, if Γ is 46% and R is 24%, R_{eff} is 65%.

According to the quantum cascade laser 1 of this embodiment, a large portion of the laser light L is reflected by the reflecting film 20 in the first regions 14be1 of the end face 14be of the core layer 14b. On the other hand, in the second region 14be2 of the end face 14be of the core layer 14b, a large portion of the laser light L is emitted from the output face 10a. Therefore, by adjusting the area ratio of the first regions 14be1 to the second region 14be2, the effective reflectivity R_{eff} of the laser light L in the output face 10a can be controlled. As the first regions 14be1 become smaller relative to the second region 14be2, the effective reflectivity of the laser light L in the output face 10a decreases. Conversely, as the first regions 14be1 become larger relative to the second region 14be2, the effective reflectivity of the laser light L in the output face 10a increases. The effective reflectivity is adjustable in the range of, for example, 20% to 80% for the light with a wavelength of 7 μm. Therefore, it is unnecessary to control the film thickness of the reflecting film 20 with high accuracy. Further, optical output power of the laser light L may be, for example, 10 mW or more.

If the reflecting film 20 has the slit 20a, the area ratio of the first regions 14be1 to the second region 14be2 can be adjusted by adjusting the width WS of the slit 20a. For example, as the width WS of the slit 20a increases, the effective reflectivity of the laser light L in the output face 10a decreases. If the width WS of the slit 20a is smaller than the width WM of the mesa waveguide 14, the effective reflectivity of the laser light L in the output face 10a can be increased. If the length HS of the slit 20a is greater than the diameter HSP of the spot size SP of the laser light L in the output face 10a, the slit 20a is located over the entire length of the spot size SP of the laser light L in the Z-axis.

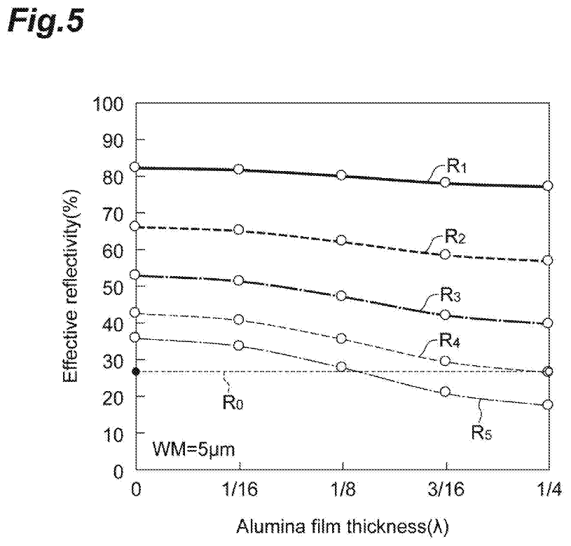

Hereinafter, referring to FIG. 5 to FIG. 9, simulations will be described taking a quantum cascade laser having the same configuration as that of a quantum cascade laser 1 as an exemplary embodiment. However, the quantum cascade laser of the present embodiment is a Fabry-Perot (FP)-type quantum cascade laser having no grating layer. This quantum cascade laser has a mesa waveguide in which an n-type InP lower cladding layer, a core layer, an n-GaInAs upper optical confinement layer, an n-InP upper cladding layer, and an n-GaInAs contact layer are formed in this order on an n-type InP substrate. The core layer has a configuration in which a unit-structure composed of active layers and injection layers including an array of GaInAs/AlInAs superlattices are laminated. WM represents a width of the mesa waveguide. The sides of the mesa waveguide are embedded by Fe—InP current blocking regions. An Au upper electrode is provided on an n-GaInAs contact layer. An Au lower electrode is provided on the back surface of the n-type InP substrate. On the entire surface of a rear end face of a laser structure, an Au high reflecting film (reflectivity is almost 100%) is provided via an alumina insulating film. On the entire surface of the front end face (an output face) of the laser structure, the Au high reflecting film (reflectivity is almost 100%) having a slit is provided via an alumina insulating film. The slit is provided at a position corresponding to the mesa waveguide. WS represents a width of the slit. The oscillation wavelength of laser light is 7.365 μm. Since the absorption of alumina with respect to this wavelength is negligibly small, the calculation was carried out by approximating the absorption of alumina to zero. The thickness of the Au high reflecting film was set to be sufficiently thick (e.g., 100 nm to 200 nm) to obtain total reflectance.

The reflectivity in the output face of the laser light depends not only on the Au—high reflecting film but also on the film thickness of the alumina insulating film. The thickness of the alumina insulating film is expressed by using as a unit of λ (=λ₀/n). The λ₀ represents the oscillation-wavelength (i.e., 7.365 μm) in vacuum. A small letter “n” represents the refractive index of alumina (i.e., about 1.3783) with respect to λ₀. The reflectivity in the output face of the laser light varies with a period of 0.5λ so as to draw a sine wave with respect to the film thickness of the alumina insulating film in an end face where the alumina insulating film is formed. Accordingly, the reflectivity will be changed repeatedly in the film thickness range of 0 to λ/4. Therefore, if the calculation is performed in consideration of the change in reflectivity in the film thickness range, the entire range of reflectivity is covered. Therefore, the effective reflectivity was calculated by fixing the width WM of the mesa waveguide at a typical width, 5 μm, in a 7-μm-wavelength quantum cascade laser, varying the thickness of the alumina film in the range of 0 to λ/4, and varying the width WS of the slit in the range of 1 to 5 μm. Calculation results are shown in FIG. 5.

FIG. 5 is a graph showing an example of relationships between the alumina film thickness and the effective reflectivity in the output face. R₀ in FIG. 5 shows the result when the output face is uncoated (in case a semiconductor surface is exposed to space as the output face). R₁ shows the result when the slit width WS is 1 μm. R₂ shows the result when the slit width WS is 2 μm. R₃ shows the result when the slit width WS is 3 μm. R₄ shows the outcome when the slit width WS is 4 μm. R₅ shows the result when the slit width WS is 5 μm. As shown in FIG. 5, as the width WS of the slit is reduced, the effective reflectivity is increased. On the other hand, as the thickness of the alumina film is increased, the effective reflectivity is gradually reduced. However, since the reduction rate is small, it can be seen that the dependence of the effective reflectivity on the alumina film thickness is small. Thus, by adjusting the width WS of the slit and the alumina film thickness, the effective reflectivity can be adjusted within the range of about 20 to 80%.

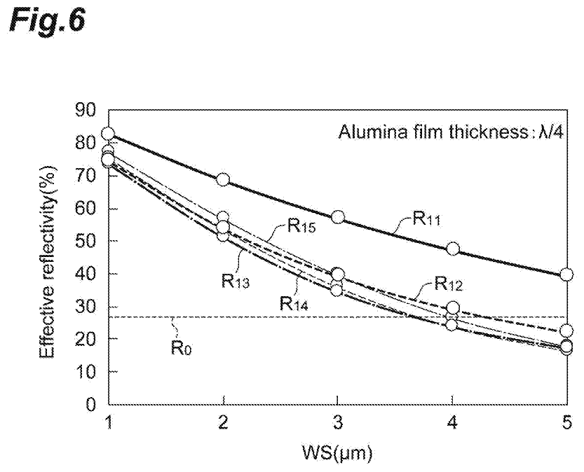

Subsequently, calculation was carried out. The alumina film thickness was fixed to V4. The width WM of the mesa waveguide was changed in the range of 1 to 5 μm. The width WS of the slit was changed in the range of 1 to 5 μm. Calculation results are shown in FIG. 6.

FIG. 6 is a graph showing an example of relationships between width WS and effective reflectivity of the slit in the output face. R₀ in FIG. 6 shows the result when the output face is uncoated. R₁₁ shows the result when the width WM of mesa waveguide is 1 μm. R₁₂ shows the result when the width WM of the mesa waveguide is 2 μm. R₁₃ shows the result when the width WM of the mesa waveguide is 3 μm. R₁₄ shows the result when the width WM of the mesa waveguide is 4 R₁₅ shows the result when the width WM of the mesa waveguide is 5 μm. As shown in FIG. 6, by adjusting the width WS of the slit, the effective reflectivity can be adjusted within the range of about 20 to 80%. In addition, the effective reflectivity is significantly larger when the width WM of the mesa waveguide is 1 μm compared to the effective reflectivity when the width WM of the mesa waveguide is 2 to 5 μm. When the width WM of the mesa waveguide is as small as 1 μm, it becomes difficult to confine light in the mesa waveguide. Consequently, the light diffused to the outside of the mesa waveguide is increased and totally reflected by the Au high reflecting film, and thus the effective reflectivity when the width WM of the mesa waveguide is 1 μm is increased.

As can be seen from FIG. 5 and FIG. 6, by adjusting the width WM of the mesa waveguide, the width WS of the slit, and the thickness of the alumina film, the effective reflectivity in the output face can be adjusted within the range of about 20 to 80%. Further, at the slit position, since the Au high reflecting film is not formed on the output face and only the alumina insulating film is formed, it is possible to avoid absorbing the laser light due to the Au high reflecting film. As a result, a higher optical output power, e.g. 10 mW or more, of the laser light can be obtained. In addition, by adjusting the width WM of the mesa waveguide, the width WS of the slit, and the thickness of the alumina film, it is also possible to obtain a lower effective reflectivity than that obtained when the output face is uncoated (R₀ in FIG.5 and FIG. 6).

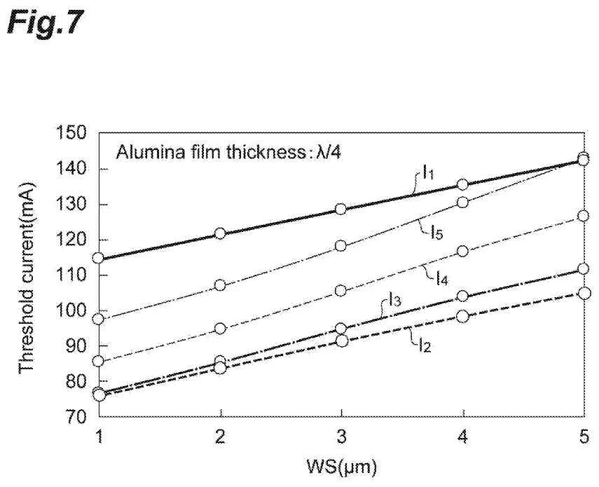

In addition, threshold currents corresponding to FIG. 6 were calculated. Calculation results are shown in FIG. 7. FIG. 7 is a graph showing an example of the relationships between the width WS of the slit and the threshold current. I₁ in FIG. 7 shows the result when the mesa waveguide width WM is 1 μm. I₂ shows the result when the mesa waveguide width WM is 2 μm. I₃ shows the result when the mesa waveguide width WM is 3 μm. I₄ shows the result when the mesa waveguide width WM is 4 μm. I₅ shows the result when the mesa waveguide width WM is 5 μm. As can be seen from FIG. 6 and FIG. 7, at each value of the width WM of the mesa waveguide, as the width WS of the slit decreases, the effective reflectivity increases, and thus the threshold current decreases. When the mesa waveguide width WM is within the range from 2 to 5 μm, the threshold current decreases as the mesa waveguide width WM decreases, provided the slit width WS is the same. This is because the width of the core layer into which the current is injected becomes smaller as the width WM of the mesa waveguide becomes smaller. However, when the width WM of the mesa waveguide is 1 μm, the threshold current becomes the maximum, even though the effective reflectivity becomes the maximum. As described above, when the width WM of the mesa waveguide is as small as 1 μm, it becomes difficult to confine the light in the mesa waveguide, and therefore it is difficult to amplify the light by stimulated emission in the core layer. Consequently, the threshold current is increased. Since the effect of increasing the threshold current due to the difficulty of amplifying the light is larger than the effect of reducing the threshold current due to the increase of the effective reflectivity, the threshold current is increased. When the width WM of the mesa waveguide is larger than 5 μm, the oscillation characteristics may become unstable by multimodal oscillation transverse mode, which is not preferable.

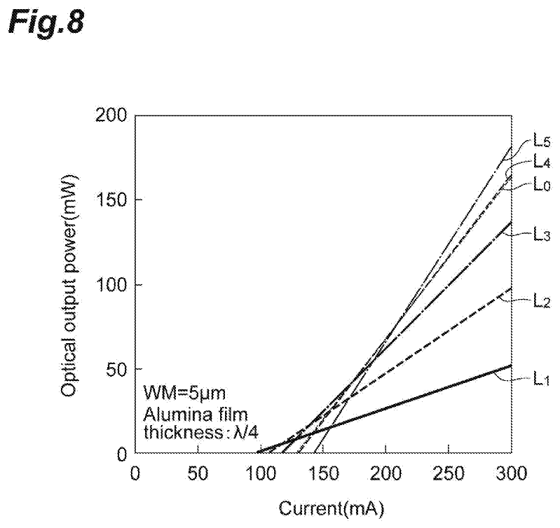

In addition, the current versus the optical output power characteristics were calculated when the width WM of the mesa waveguide was fixed to 5 μm, the thickness of the alumina film was fixed to λ/4, and the width WS of the slit was changed. Calculation results are shown in FIG. 8. FIG. 8 is a graph showing an example of the relationships between the current and the optical output power when the width of the slit is changed. L₀ in FIG. 8 shows the result when the output face is uncoated. L₁ shows the result when the width WS of the slit is 1 μm. L₂ shows the result when the width WS of the slit is 2 μm. L₃ shows the result when the width WS of the slit is 3 μm. L₄ shows the result when the width WS of the slit is 4 μm. L₅ shows the result when the width WS of the slit is 5 μm. As shown in FIG. 8, when the width WS of the slit becomes smaller, the effective reflectivity increases, so that the threshold current can be reduced. However, since the extraction of the emitted light from the slit becomes difficult, the slope-efficiency of the emitted light is reduced. Therefore, it is difficult to obtain a high output. On the other hand, as the width WS of the slit increases, the effective reflectivity decreases, and thus the threshold current increases. However, since the extraction of the emitted light from the slit is facilitated, the slope-efficiency of the emitted light is increased. Therefore, it is easy to obtain a high output. In addition, when the width WS of the slit is 4 μm, substantially the same result as in the case where the output face is not coated is obtained. This is because, as shown in FIG. 5 and FIG. 6, when the width WS of the slit is 4 μm, the effective reflectivity is substantially the same as that obtained when the output face is not coated.

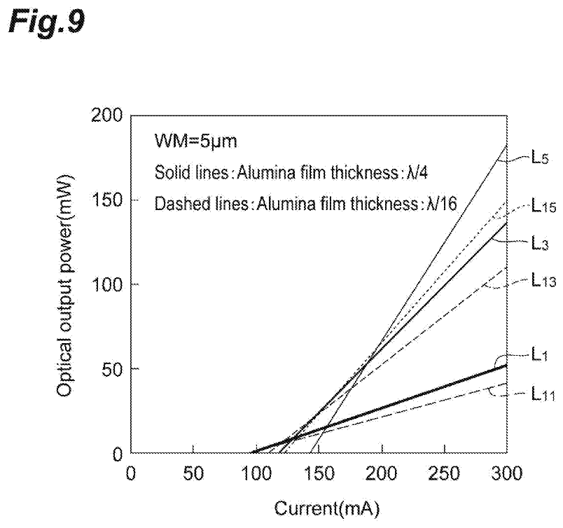

The current versus optical output power characteristics were calculated when the width WM of the mesa waveguide was fixed to 5 μm, the thickness of the alumina film was λ/4 or λ/16, and the width WS of the slit was changed. Calculation results are shown in FIG. 9. FIG. 9 is a graph showing an example of the relationships between the current and the optical output power when the width of the slit and the thickness of the alumina film are changed. L₁ in FIG. 9 shows the result when the thickness of the alumina film is λ/4 and the width WS of the slit is 1 μm. L₁₁ shows the result when the width WS of the slit is 1 μm and the thickness of the alumina film is λ/16. L₃ shows the result when the thickness of the alumina film is λ/4 and the width of the slit WS is 3 λm. L₁₃ shows the result when the width WS of the slit is 3 μm and the thickness of the alumina film is λ/16. L₅ shows the result when the thickness of the alumina film is λ/4 and the width WS of the slit is 5 μm. L₁₅ shows the result when the width WS of the slit is 5 μm and the thickness of the alumina film is λ/16. As described in FIG. 5, when the width WS of the slit is the same, the effective reflectivity is reduced as the thickness of the alumina film increases. Thus, as shown in FIG. 9, when the width WS of the slit is the same, the threshold current increases as the thickness of the alumina film increases, while high power is obtained. When the alumina film thickness is the same, the threshold current increases as the width WS of the slit increases, while high power is obtained. This is the same as the trend shown in FIG. 8.

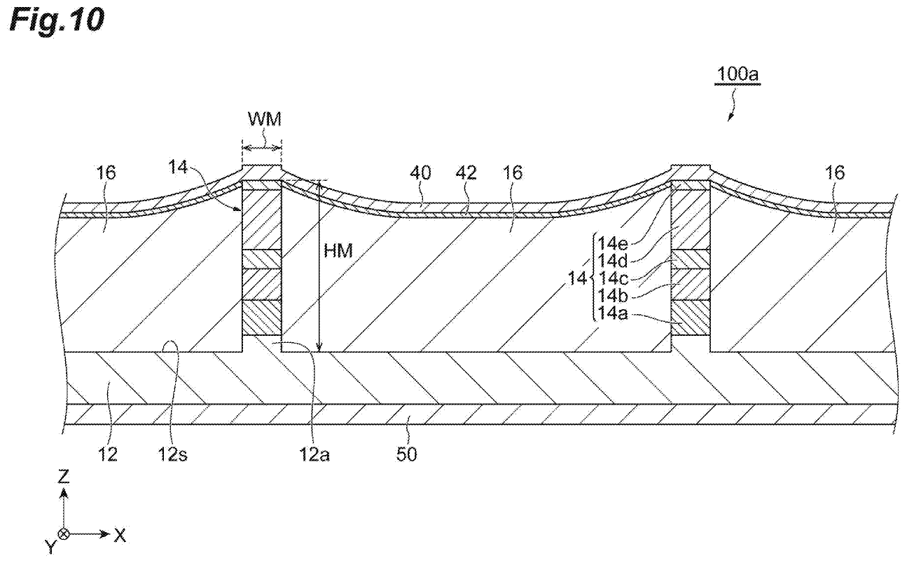

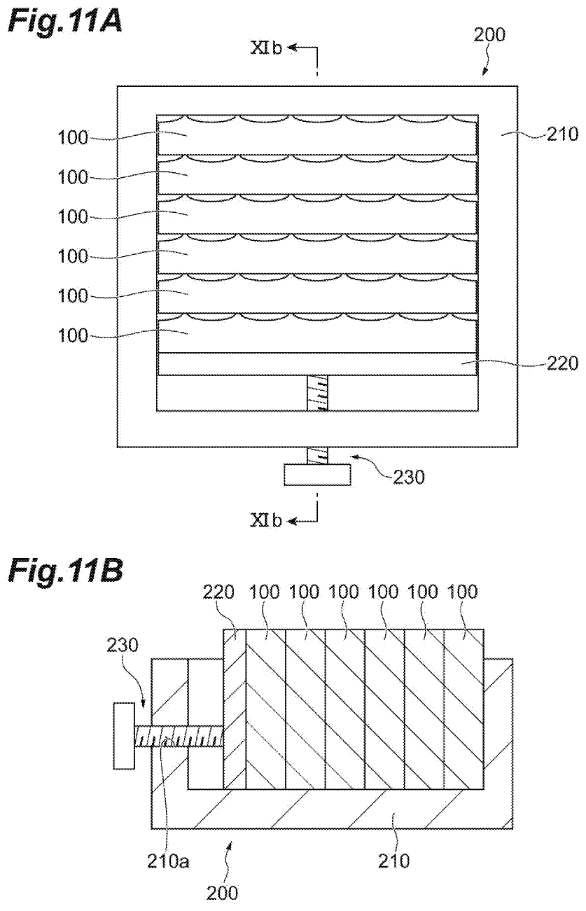

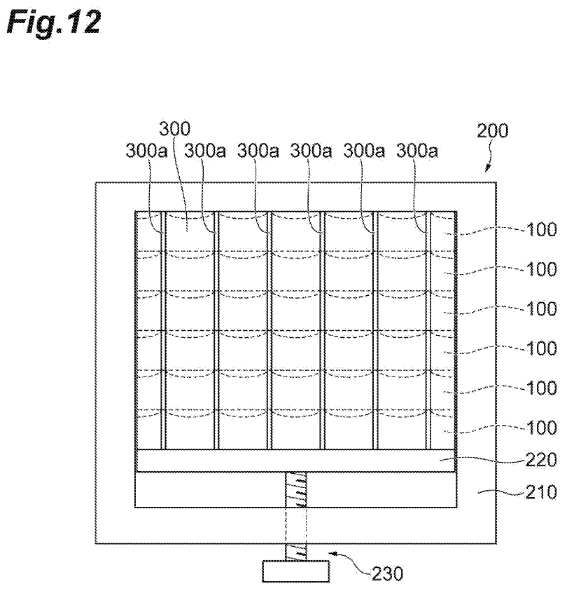

Next, referring to FIG.10 to FIG. 12, an example of a method of manufacturing a quantum cascade laser 1 according to the present embodiment will be described. FIG. 10 is a diagram illustrating one step in a manufacturing process of a quantum cascade laser according to an embodiment. FIG. 11A is a top view showing one step in the manufacturing process of the quantum cascade laser according to the embodiment, and FIG. 11B is a cross-sectional view taken along line XIb-XIb of FIG. 11A. FIG. 12 is a top view showing one step in the manufacturing process of a quantum cascade laser according to one embodiment. For example, the quantum cascade laser 1 is produced as follows.

First, as shown in FIG. 10, a substrate product 100a comprising a plurality of mesa waveguides 14 provided on a substrate 12 is prepared. The substrate product 100a has a structure in which a plurality of laser structures 10 shown in FIG.1 to FIG. 4 are arranged in an X-axis direction and a Y-axis direction and connected to each other. The substrate product 100a comprises current blocking regions 16 provided between the adjacent mesa waveguides 14. A passivation film 42 is provided on the current blocking regions 16. An upper electrode 40 is provided on the mesa waveguides 14 and the passivation film 42. A lower electrode 50 is provided on the back surface of the substrate 12. For example, the substrate product 100a is obtained as follows.

For example, a plurality of semiconductor layers are sequentially grown on a substrate such as an n-type InP substrate by, for example, an organometallic vapor phase epitaxy (OMVPE) method or a molecular beam epitaxy (MBE) method. The plurality of semiconductor layers are a lower cladding layer 14a, a core layer 14b, a grating layer 14c, an upper cladding layer 14d, and a contact layer 14e. In one example, the semiconductor layer serving as the lower cladding layer 14a is a Si-doped InP layer, the semiconductor layer serving as the core layer 14b is a laminate of active layers and injection layers comprising an array of GaInAs/AlInAs superlattices, the semiconductor layer serving as the grating layer 14c is a Si-doped GaInAs layer, the semiconductor layer serving as the upper cladding layer 14d is a Si-doped InP layer, and the semiconductor layer serving as the contact layer 14e is a Si-doped InGaAs layer. On the semiconductor layer serving as the grating layer 14c, the recesses 14c1 are formed by photolithography and etching.

Next, the semiconductor layers are dry-etched using insulating masks for forming the mesa waveguides 14, whereby stripe-shaped mesa waveguides 14 are formed. In one example, the height HM of the mesa waveguides 14 from the principal surface 12s of the substrate 12 is 7 μm and the width WM of the mesa waveguides 14 is 5 μm. Thereafter, the current blocking regions 16 for burying the side surfaces of the mesa waveguides 14 are grown. The current blocking regions 16 are formed by, for example, an OMVPE method. The current blocking regions 16 are, for example, Fe-doped InP-regions. The thickness of the current blocking regions 16 in the height direction (Z-axis direction) of the mesa waveguides 14 becomes smaller as it moves away from the mesa waveguides 14. Therefore, the mesa waveguides 14 protrude with respect to the current blocking regions 16 when viewed from the Y-axis direction. Therefore, the position of the mesa waveguides 14 can be visually recognized by using the exposure device, the focused ion beam (FIB) device, or the like for photolithography. Subsequently, after the insulating masks are removed, a passivation film 42 is formed over the mesa waveguides 14 and the current blocking regions 16. The passivation film 42 is, for example, SiO₂ layers. Thereafter, a stripe-shaped opening is formed in the passivation film 42 on the mesa waveguides 14, and the contact layer 14e is exposed in the stripe-shaped opening. Subsequently, the upper electrode 40 being in contact with the contact layer 14e is formed by, for example, vapor deposition. The upper electrode 40 is, for example, Ti/Pt/Au film. Thereafter, the back surface of the substrate 12 is polished to reduce the thickness of the substrate 12 to, for example, 100 μm to 200 μm. Next, the lower electrode 50 is formed on the back surface of the substrate 12 by, for example, vapor deposition. The lower electrode 50 is, for example, Ge/Au film.

Next, a plurality of laser bars 100 are obtained by cutting the substrate 12 along, for example, grid-like cutting lines. An example of the cutting is a cleavage. Each laser bar 100 has a structure in which a plurality of the laser structures 10 shown in FIG.1 to FIG. 4 are arranged along the X-axis and connected to each other.

Next, with the first protective plate disposed on each of the upper electrode 40 and the lower electrode 50, passivation films 22 and 32 are sequentially formed on a front end face (a face which serves as the output face 10a) and a rear end face (a face which serves as the reflection face 10b) of the laser bar, respectively. The passivation films 22 and 32 are formed, for example, by sputtering or CVD. In the Y-axis direction, the length of the first protective plate is smaller than the resonator length of the laser bar (the length L1 of the laser structure 10). Subsequently, the first protective plate is removed, and a metal film which serves as the reflecting film 20 or the reflecting film 30 are formed on each of the passivation films 22 and 32 by, for example, vapor deposition, with the second protective plate disposed on each of the upper electrode 40 and the lower electrode 50. In the Y-axis direction, the length of the second protective plate is longer than the first protective plate. As a result, the distance between the edge of the reflecting film 20 or the reflecting film 30 and the edge of the upper electrode 40 or the lower electrode 50 can be increased, so that short-circuiting can be suppressed.

Next, a plurality of the laser bars 100 are fixed using a jig 200, as shown in FIG. 11A and FIG. 11B. The jig 200 includes a metal container 210 for receiving a plurality of the laser bars 100, a pressing plate 220 accommodated in the metal container 210 for pressing the plurality of the laser bars 100, and a pressing screw 230 having a front end abutting the pressing plate 220. The metal container 210 is, for example, a box made of aluminum. The pressing screw 230 is screwed into a screw hole 210a provided on the metal container 210 and is rotated to move in one direction. When the pressing screw 230 moves, the pressing plate 220 is pressed and moved by the front end of the pressing screw 230.

In order to fix a plurality of the laser bars 100 by using the jig 200, first, the plurality of the laser bars 100 are arranged in the metal container 210 by using, for example, a tweezer such that the front end face of the laser bar 100 (the face which serves as the output face 10a) is an upper surface. The front end face of the laser bar 100 is higher than the height of the metal container 210. A plurality of the laser bars 100 are arranged along traveling direction of the pressing screw 230. The pressing plate 220 is disposed between a plurality of the laser bars 100 and the pressing screw 230. The plurality of the laser bars 100 are then pressed against the inner wall of the metal container 210 by rotating the pressing screw 230 to move the pressing plate 220. In this manner, the plurality of the laser bars 100 are fixed.

Next, as shown in FIG. 12, after forming a resist film 300 on the plurality of the laser bars 100 by, for example, spin-coating, a plurality of slits 300a are formed on the resist film 300 by exposure and development. In the exposure, for example, a non-contact photomask and a stepper are used. Since the height HM of the mesa waveguides 14 is larger than the thickness of the current blocking regions 16, the position of the mesa waveguides 14 can be visually recognized in the exposure device for photolithography. The slits 300a can be formed on the mesa waveguides 14 by aligning the patterns of the photomask with the positions of the mesa waveguides 14. Next, the metal film is wet-etched to form the reflecting film 20 having a slit 20a. When the metal film comprises gold, the etchant is, for example, a mixed solution of iodine and potassium iodide. This etchant selectively etches the metal film and does not etch the passivation film 32. Instead of wet etching, dry etching (RIE or ion milling) may be used. After the etching, the resist film 300 is removed.

The slit 20a of the reflecting film 20 may be formed using a FIB device without using a resist film. In this case, first, a plurality of the laser bars 100 are fixed using the jig 200, as shown in FIG. 11A and FIG. 11B. Next, the ion beam is scanned along the mesa waveguides 14 using the FIB device. Thus, a portion of the metal film irradiated with the ion beam is removed by sputtering. Thus, the slit 20a is formed. The alignment of the ion beam scan is performed with the mesa waveguides 14 projecting relative to the current blocking regions 16 as a landmark. In the FIB device, the alignment of the ion beam can be performed each time for each mesa waveguide 14. Thus, by using the FIB device, alignment accuracy between the slit 20a and the mesa waveguides 14 is improved as compared to the method shown in FIG.12 in which the resist film is utilized.

The laser bars 100 are then removed from the jig 200 and the laser bars 100 are cut along the cutting line located between the adjacent mesa waveguides 14. Thus, a plurality of quantum cascade lasers 1 are obtained. Examples of cutting are cleavage, dicing, etc.

While preferred embodiments of the present disclosure have been described in detail above, the present disclosure is not limited to the above embodiments.

For example, the quantum cascade laser 1 may not include the grating layer 14c. In this case, the quantum cascade laser 1 operates as a Fabry-Perot laser rather than a distributed feedback laser.

While the principles of the present invention have been illustrated and described in preferred embodiments, it will be appreciated by those skilled in the art that the invention may be modified in arrangement and detail without departing from such principles. The present invention is not limited to the specific configurations disclosed in this embodiment. Accordingly, it is claimed that all modifications and changes come from the scope of the claims and their spirit.

What is claimed is:

1. A quantum cascade laser comprising:
a laser structure having an output face for emitting laser light in a first direction; and
a reflecting film provided on the output face,
wherein
the laser structure includes a core layer,
the output face includes an end face of the core layer,
the end face includes a first region and a second region that differs from the first region, and
the reflecting film covers the first region and does not cover the second region.

2. The quantum cascade laser according to claim 1, wherein
the laser structure includes a mesa waveguide including the core layer,
the mesa waveguide extends in the first direction and projects in a second direction intersecting the first direction,
the reflecting film has a slit provided on the second region, and
the slit extends in the second direction.

3. The quantum cascade laser according to claim 2, wherein the slit has a width narrower than a width of the mesa waveguide.

4. The quantum cascade laser according to claim 2, wherein the slit has a length greater than a diameter of a spot size of the laser light in the output face in the second direction.

5. The quantum cascade laser according to claim 2, wherein a width of the slit is 1 μm to 5 μm.

6. The quantum cascade laser according to claim 2, wherein a width of the mesa waveguide is 2 μm to 5 μm.

7. The quantum cascade laser according to claim 2, wherein the reflecting film is provided on the output face via a passivation film provided on the output face in the slit.

8. The quantum cascade laser according to claim 1, wherein a thickness of the reflecting film is 50 nm or more.
